(19) United States
(12) Patent Application Publication
(10) Pub. No.: US 2008/0013751 A1
(43) Pub. Date: Jan. 17, 2008

(54) VOLUME DEPENDENT AUDIO FREQUENCY GAIN PROFILE

(76) Inventor: Per HISELIUS, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/457,832

(22) Filed: Jul. 17, 2006

(51) Int. Cl. H03G 9/00

(52) U.S. Cl. 381/102

(57) ABSTRACT

An electronic equipment is provided that includes an audio reproduction circuit for receiving an audio signal and reproducing the audio signal in accordance with a preselected audio frequency gain profile. In addition, the electronic equipment includes a volume gain control circuit for providing user adjustable volume gain to the audio signal reproduced by the audio reproduction circuit. The electronic equipment also includes an audio output for outputting the reproduced audio signal. The audio reproduction circuit alters the preselected audio frequency gain profile as a function of the user adjusted volume gain.

### TECHNICAL FIELD OF THE INVENTION

The present invention relates generally to electronic equipment, and more particularly to electronic equipment for reproducing audio.

### DESCRIPTION OF THE RELATED ART

Portable electronic equipment, and particularly mobile phones, have become enormously popular over the last decade. Whether for professional or personal use, seemingly everybody, young and old alike, has their own mobile phone for communicating with friends, family, customers, colleagues, etc.

Mobile phones today offer a wide variety of features in addition to conventional two-way calling among parties. For example, mobile phones typically offer three-way calling, call waiting, caller identification (ID), etc., as found in conventional land-based telephones. Moreover, mobile phones nowadays typically offer additional features such as built-in media players, cameras, web-browsing, email capability, etc. Such features serve to enhance the productivity and enjoyment level of the user.

Users of mobile phones frequently enjoy a large degree of flexibility in personalizing their mobile phone. Such personalization may include features such as ring tones, backgrounds, banners, etc. Mobile phones having media players provide even further enhancement features such as advanced audio and video control. For example, some mobile phones now come with equalization controls that allow a user to adjust audio reproduction to suit the user's own personal tastes, e.g., more or less bass, treble, mid-range, etc. Such adjustments may be performed manually via a menu screen or the like. Alternatively, a user may select from among predefined equalization patterns, e.g., music genre specific patterns for rock, pop, talk, classical, etc.

On the other hand, there are some audio constraints placed on some types of electronic equipment, and particularly mobile phones. For example, in order to preserve the listening experience for a user during conventional mobile phone communications, mobile phones typically are designed to have a particular receive loudness rating (RLR). The RLR takes into account the gain of the mobile phone receiver and the efficiency of the mobile phone speaker.

Further, there are safety considerations particularly regarding mobile phones. Whether during mobile phone communications or audio reproduction, high sound levels from the mobile phone speaker and/or handsfree headset can lead to temporary or permanent hearing loss. Moreover, high sound levels can distract or prevent a user from hearing environmental sounds. This is particularly important in the case of mobile phones used by those operating automobiles or other dangerous equipment. Excessive sound levels may prevent the user from hearing ambulance sirens, warning signals, etc.

Consequently, increasing regulation regarding sound levels on mobile phones and other electronic equipment is expected. Such regulation is expected to limit sound levels separately or in conjunction with the RLR. Such regulation may be beneficial particularly for safety concerns. However, such regulation will likely limit the user's ability to personalize audio reproduction insofar as overall sound level, etc. For example, the user may not be able to enjoy his or her preferred level of bass reproduction due to limits involving RLR, maximum sound levels, and/or a combination thereof.

In view of the aforementioned shortcomings associated with conventional electronic equipment, there is a strong need in the art for electronic equipment that helps preserve the user's flexibility in personalizing audio reproduction. More particularly, there is a strong need in the art for electronic equipment that allows a user to still enjoy dynamic audio reproduction despite sound level limits due to RLR, maximum sound levels, etc.

### SUMMARY

According to one aspect of the invention, an electronic equipment is provided that includes an audio reproduction circuit for receiving an audio signal and reproducing the audio signal in accordance with a preselected audio frequency gain profile. The electronic equipment further includes a volume gain control circuit for providing user adjustable volume gain to the audio signal reproduced by the audio reproduction circuit. In addition, the electronic equipment includes an audio output for outputting the reproduced audio signal. Moreover, the audio reproduction circuit alters the preselected audio frequency gain profile as a function of the user adjusted volume gain.

According to another aspect of the invention, the audio reproduction circuit adjusts the audio frequency gain profile by reducing the gain at relatively lower audio frequencies as a result of the user adjusted volume gain being increased.

In accordance with another aspect of the invention, the relatively lower audio frequencies include frequencies approximately within the band of 125 Hz to 350 Hz.

According to yet another aspect of the invention, the audio reproduction circuit adjusts the audio frequency gain profile by increasing the gain at relatively higher audio frequencies as a result of the user adjusted volume gain being increased.

According to still another aspect of the invention, the relatively higher audio frequencies include frequencies in the band of approximately 1 KHz to 4 KHz.

With yet another aspect of the invention, the audio reproduction circuit adjusts the audio frequency gain profile to increase the intelligibility of voice signals within the reproduced audio signal as a result of the user adjusted volume gain being increased.

In accordance with another aspect of the invention, the audio reproduction circuit alters the preselected audio frequency gain profile at relatively higher user adjusted volume gains but does not alter the preselected audio frequency gain profile at relatively lower user adjusted volume gains.

According to another aspect of the invention, the audio reproduction circuit alters the preselected audio frequency gain profile so as to maintain a sound level below a preselected level despite the user adjusted volume gain being increased.

In accordance with still another aspect of the invention, the audio reproduction circuit keeps the preselected audio frequency gain profile substantially the same throughout a majority of the volume gain adjustment provided by the volume gain control circuit, and alters the preselected audio frequency gain profile substantially only towards the maximum volume gain provided by the volume gain control circuit.

In accordance with yet another aspect of the invention, the audio reproduction circuit includes a gain profile adjustment circuit that scales the preselected audio frequency gain profile in order to alter the preselected audio frequency gain profile as a function of the user adjusted volume gain.

According to an additional aspect of the invention, the preselected audio frequency gain profile and gain profile adjustment circuit are implemented via a lookup table.

In yet another aspect of the invention, the preselected audio frequency gain profile is user adjustable.

According to another aspect of the invention, the user may select the preselected audio frequency gain profile from among a plurality of audio frequency gain profiles.

With respect to yet another aspect of the invention, at least one of the plurality of audio frequency gain profiles is configured for improved music reproduction, and at least another one of the plurality of audio frequency gain profiles is configured for improved voice reproduction.

According to another aspect of the invention, the electronic equipment includes at least one of a mobile phone, personal audio player, and personal video player.

In accordance with another aspect of the invention, the electronic equipment is a mobile phone.

According to yet another aspect of the invention, the mobile phone comprises a speaker and a hands-free headset output, each of which may be coupled to the audio output.

With still another aspect of the invention, the electronic equipment is a wireless hands-free headset.

In yet another aspect of the invention, the headset includes a Bluetooth receiver.

According to still another aspect of the invention, a method is provided for controlling gain in an electronic equipment. The method includes the steps of reproducing the audio signal in accordance with a preselected audio frequency gain profile; providing adjustable volume gain to the audio signal reproduced by the audio reproduction circuit; and altering the preselected audio frequency gain profile as a function of the adjustable volume gain.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF THE DRAWINGS

FIG. 1 is a perspective view of a mobile phone including an audio reproduction circuit for altering a predefined audio frequency gain profile as a function of a user adjusted volume gain in accordance with an exemplary embodiment of the present invention;

FIG. 2 is a block diagram of an exemplary audio reproduction circuit in accordance with the present invention;

FIG. 3 represents an exemplary audio frequency gain profile of the audio reproduction circuit of FIG. 2, together with the effects of maximum and minimum volume gain in accordance with conventional operation;

FIG. 4 represents another exemplary audio frequency gain profile of the audio reproduction circuit of FIG. 2, together with the effects of unrestricted maximum and minimum volume gain in accordance with conventional operation;

FIG. 5 represents the audio frequency gain profile shown in FIG. 4, together with the effects of simple restricted maximum and minimum volume in accordance with conventional operation;

FIG. 6 represents the audio frequency gain profile shown in FIG. 4, together with the effects of altering the audio frequency gain profile as a function of a volume gain in accordance with an exemplary embodiment of the present invention;

FIG. 7 represents the audio frequency gain profile shown in FIG. 4, together with the effects of another example of altering the audio frequency gain profile as a function of a volume gain in accordance with an exemplary embodiment of the present invention;

FIG. 8 represents an exemplary lookup table suitable for altering the audio frequency gain profile in accordance with the embodiment of FIG. 6;

FIG. 9 represents an exemplary lookup table suitable for altering the audio frequency gain profile in accordance with the embodiment of FIG. 7; and

FIG. 10 is a block diagram of the mobile phone of FIG. 1 in accordance with an exemplary embodiment of the present invention.

### DETAILED DESCRIPTION OF EMBODIMENTS

The present invention will now be described with reference to the drawings, wherein like reference numerals refer to like elements throughout.

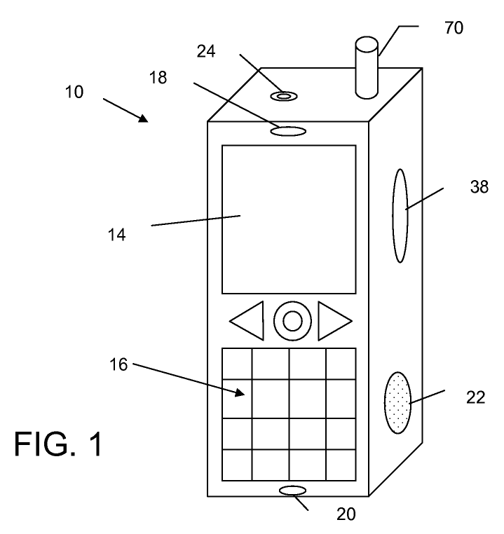

FIG. 1 illustrates electronic equipment 10 in accordance with an exemplary embodiment of the present invention. In the exemplary embodiment, the electronic equipment 10 is a mobile phone for use in carrying out mobile communications. Those having ordinary skill in the art will appreciate, however, that the present invention has utility with virtually any type of electronic equipment that involves the reproduction of audio. Accordingly, the scope of the present invention in the broadest sense is not intended to be limited to a mobile phone.

The mobile phone 10 as shown in FIG. 1 has a “brick” or “block” design type housing. It will be appreciated, however, that other type housings such as clamshell or slide-type housings may be utilized without departing from the scope of the invention. The mobile phone 10 includes a conventional display 14 and keypad 16. The display 14 displays information to a user such as operating state, time, phone numbers, contact information, various navigational menus, etc., which enable the user to utilize the various features of the mobile phone 10. Similarly, the keypad 16 may be conventional in that it provides for a variety of user input operations. For example, the keypad 16 typically includes alphanumeric keys for allowing entry of alphanumeric information such as telephone numbers, phone lists, contact information, notes, etc. In addition, the keypad 16 typically includes special function keys such as a “call send” key for initiating or answering a call, and a “call end” key for ending, or “hanging up” a call. Special function keys may also include menu navigation keys, for example, for navigating through a menu displayed on the display 14 to select different phone functions, profiles, settings, etc., as is conventional. Other keys included in the keypad 16 may include a volume up/down keys, on/off power key, as well as various other keys such as a web browser launch key, camera key, etc.

In the particular embodiment of FIG. 1, the mobile phone 10 includes the display 14 and separate keypad 16. In an alternative embodiment, the display 14 may comprise a touchscreen which itself includes one or more keys. In yet another embodiment, the display 14 may comprise a touchscreen that includes all or substantially all of the keys used to operate the phone 10 so as to include a very limited keypad 16 or no keypad 16 at all. As will be appreciated, the particular form and function of the keys included in the keypad 16 or touchscreen/display 14 are not germane to the invention in its broadest sense.

As will be described in more detail below, the mobile phone 10 includes a speaker 18 in combination with a microphone 20. By holding the mobile phone 10 up to his or her ear in a conventional manner, A user can communicate with another party by speaking into the microphone 20, and may hear the other party via the speaker 18. In addition, the mobile phone 10 may include a larger speaker 22 within the phone housing for reproducing sound, particularly in the case where the user utilizes speakerphone capabilities of the mobile phone 10. Still further, the mobile phone 10 may include a handsfree headset jack 24. A headset having one or two earbuds and a microphone may be connected to the mobile phone 10 via the headset jack 24 to allow handsfree communication using the mobile phone 10. Still further, the mobile phone 10 may include a Bluetooth or other wireless transceiver (not shown) that allows handsfree operation using a Bluetooth or other wireless type headset as will be appreciated.

The mobile phone 10 also includes media player functionality as will be described in more detail below. The media player functionality enables a user to reproduce media files (e.g., audio and/or video) similar to a portable media player. The media files may be stored in memory within the mobile phone (e.g., via flash memory, hard drive, etc.). Alternatively, the media files may be streamed via the mobile communication network. The particular manner in which media files are obtained is not germane to the present invention, and therefore further detail is omitted for sake of brevity.

The mobile phone 10, in reproducing such media files, is configured to be able to reproduce the audio portion so that the user may hear the audio via one or more of the speakers or handsfree devices. For example, the user may listen to music files via either of the speakers 18 or 22. Alternatively, the user may listen to the music files via a handsfree headset connected via the jack 24 or wireless transceiver (e.g., Bluetooth).

Moreover, the mobile phone 10 allows the user to adjust the frequency gain profile of the reproduced audio as will be explained in more detail below. Briefly, the user may adjust the frequency response of the mobile phone 10 so as to suit the user's tastes insofar as, for example, the amount of bass, treble, etc. The mobile phone 10 may be configured to provide such adjustment via menu selections on the display 14 together with manipulation of the keys on the keypad 16 as will be appreciated. The mobile phone 10 may be configured to allow discrete manipulation of the frequency gain profile with respect to different audio frequency bands (analogous to gain settings as found in a conventional audio equalizer). In addition, or in the alternative, the user may select from among multiple predefined audio frequency gain profiles via the menu selections. For example, the mobile phone 10 may be preconfigured to allow a user to select from among audio frequency gain profiles particularly suited for different genres, e.g., classical, rock, pop, talk, etc.

The particular audio frequency gain profile selected by the user allows the user to enjoy audio reproduction via the speakers 18, 22 or desired handsfree headset with gain levels most pleasing to the user. Thus, the mobile phone 10 provides a user with the desired flexibility of being able to adjust the frequency gain profile to suit the user's tastes in reproduced audio. Unlike conventional mobile phones having such equalization features as discussed above, however, the mobile phone 10 of the present invention is configured to better preserve the user's flexibility in personalizing audio reproduction even in the event of sound level or RLR regulations or limits. As will be described in more detail below, the mobile phone 10 includes an audio reproduction circuit that alters the audio frequency gain profile as a function of user selected volume gain. Generally speaking, a user is able to freely define an audio frequency gain profile based upon which the mobile phone 10 reproduces the audio signal. In the event, however, the user adjusts the volume gain of the audio reproduction in a manner that would otherwise cause any sound level limits (e.g., RLR, maximum sound level, etc.) to be exceeded, the mobile phone 10 alters the audio frequency gain profile in order to remain within the sound level limits.

According to a particular example of the present invention, the mobile phone 10 allows a user to select an audio frequency gain profile, either by discrete gain selections or by selection from among predefined audio frequency gain profiles. For example, the user may select a profile with a heavy emphasis on bass reproduction in order to better enjoy listening to rock music via a handsfree headset. If the user receives a telephone call during such listening, the user may find it difficult to hear the voice signals that exist more in the mid range of the audio band due to the heavy bass emphasis. Conventionally, if the user simply was to increase the volume of the mobile phone so as to increase the gain of the reproduced voice signal, the amount of volume gain available may be insufficient due to overall sound level limits built into the phone (e.g., to ensure safety requirements or the like are satisfied). Thus, even with an increase in volume it may be difficult for the user to hear the voice signals in a conventional mobile phone. With the present invention, however, the audio reproduction circuit within the mobile phone 10 automatically alters the selected audio frequency gain profile as a function of the user adjusted volume gain. Consequently, as the user increases the volume in an attempt to better hear the voice at the other end of the call, the mobile phone 10 adjusts the audio frequency gain profile to reduce the emphasis on bass reproduction and to increase the emphasis on the mid-range frequency components. As a result, the user is better able to understand the voice communication without having to manually adjust the frequency gain profile. At the same time, the mobile phone 10 may remain in compliance with any sound level limits, etc. When the user reduces the volume gain, the audio reproduction circuit automatically returns the audio frequency profile so as to be the same prior to the increase in volume. Thus, the user may return to enjoying music or the like.

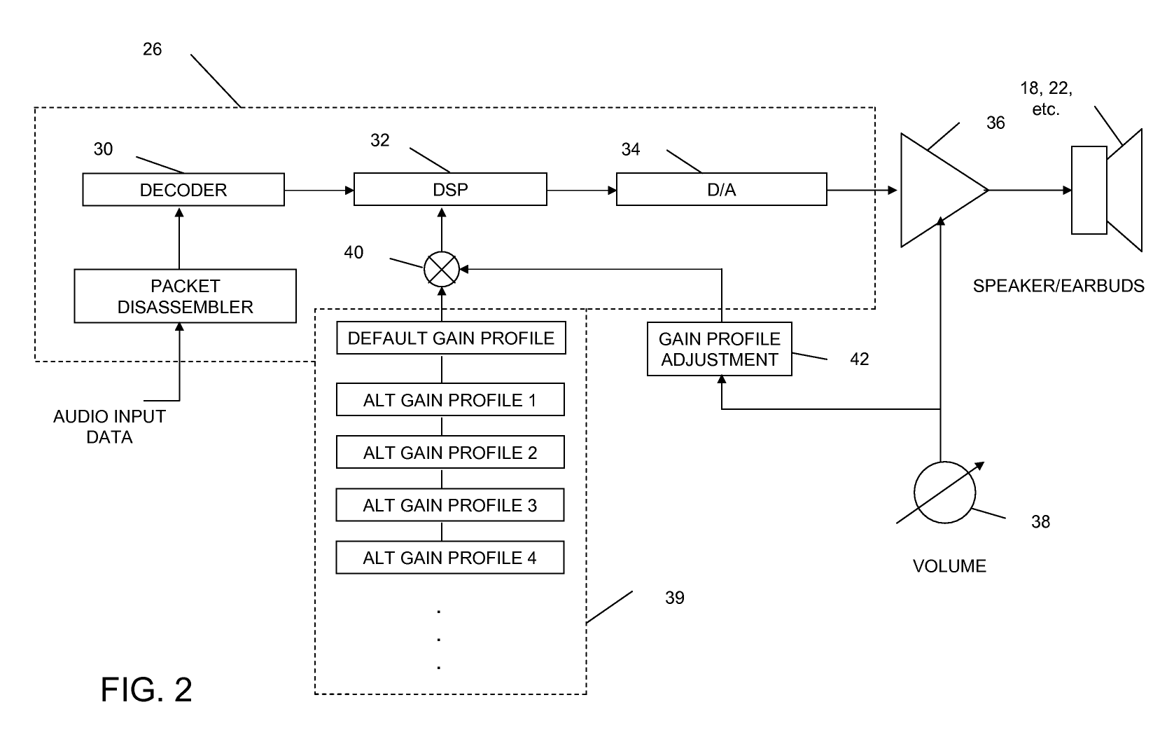

Referring now to FIG. 2, shown is an audio reproduction circuit 26 included in the exemplary embodiment of the mobile phone 10. The audio reproduction circuit 26 receives digital audio input data via communications over a mobile phone network, from an internal memory or hard drive within the mobile phone 10, etc. The audio input data is input to a package disassembler 28 included in the audio reproduction circuit 26. Using known techniques, the package disassembler 28 disassembles the packet carrying the audio data in the event the audio data is received in packetized format. The audio input data then proceeds to a decoder 30 that decodes the audio input data based on the particular format of the audio data. For example, the audio input data may be a music file in AC-3, mp3, wma, or any other of a variety of other audio formats. Moreover, the audio input data may be the voice signal received from a party at the other end of a mobile phone communication.

The decoder 30 decodes the audio input data so as to produce decoded audio input data that is then input to a digital signal processor (DSP) 32 included in the audio reproduction circuit 26. Again using known techniques, the DSP 32 processes the audio input data prior to outputting the processed audio data to a digital-to-analog converter (D/A) 34. The D/A converter 34 converts the digital audio data signal to an analog audio data signal that is in turn input to an analog volume gain amplifier 36 included in the mobile phone 10. The user of the mobile phone 10 may adjust the volume gain of the amplifier 36 via a volume control key 38, for example. The volume control key 38 may be implemented via the keypad 16 or the like as discussed above in relation to FIG. 1, or simply be a discrete key as shown in FIG. 1. The amplified audio data is then provided to the speaker 18, speaker 22, headset jack 24, etc. via the appropriate audio output so as to be reproduced for the user's enjoyment.

It will be appreciated that in another embodiment, the volume gain control circuit represented by the amplifier 36 and volume control key 38 may be carried out digitally rather than by analog circuitry. More specifically, the amplifier 36 may be a digital amplifier used to amplify the audio data prior to being input to the D/A converter 34. Moreover, the digital data may be transmitted via wireless transceiver to a wireless handsfree headset prior to any D/A conversion as will be appreciated. The present invention is intended to cover each and every such embodiment.

Using known techniques, the DSP 32 is configured to process the audio input data in accordance with a preselected audio frequency gain profile. In some conventional phones the particular audio frequency gain profile is fixed, whereas in other conventional phones the user may adjust the audio frequency gain profile as discussed above. In the exemplary embodiment of the present invention, the DSP 32 is configured so as to have a standard or default audio frequency gain profile that the DSP 32 of the mobile phone 10 utilizes in the event the user does not make a custom selection. In addition, the user may select from among a plurality of predefined audio frequency gain profiles 39 (e.g., Alternate Gain Profiles 1-4). By appropriate menu navigation, the user can select among the different profiles, and the selected profile is provided to the DSP 32. As yet another alternative, the user may select a profile via individual gain selections for the different frequency bands within the profile. Each of the various profiles may be stored in memory within the mobile phone 10 as will be appreciated.

Regardless of the particular manner in which the user selects (including via default selection) a particular audio frequency gain profile, the profile is provided to the DSP 32 via what is schematically shown as a multiplier/scaler 40 in FIG. 2. The DSP 32 in turn processes the audio input data in accordance with the selected audio frequency gain profile. Thus, if the user selects an audio gain profile that emphasizes select bass and treble frequencies, the DSP 32 will emphasize the select bass and treble frequencies in processing the audio data prior to the audio data being reproduced via the speakers, headsets, etc.

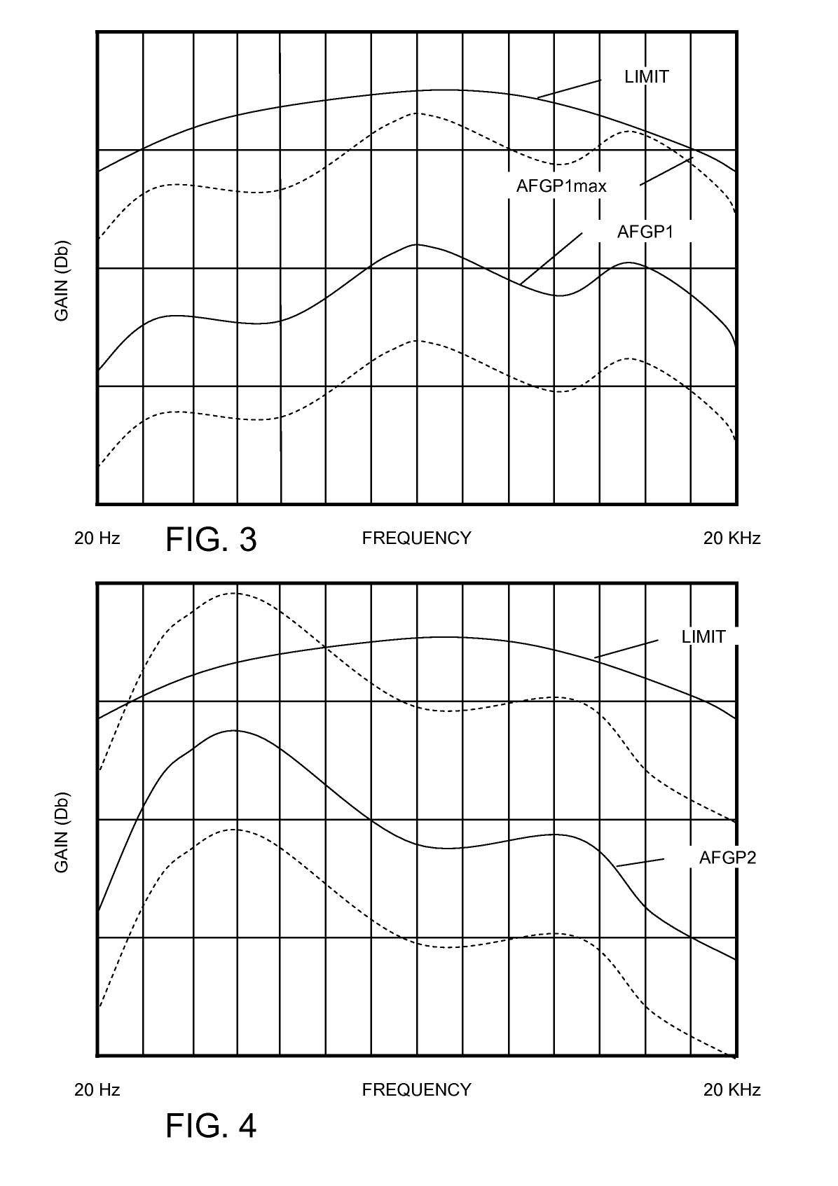

The mobile phone 10 of the present invention further includes a gain profile adjustment circuit 42. The gain profile adjustment circuit 42 receives as an input a signal indicative of the user adjusted volume gain via the volume control key 38. In accordance with the principles described more fully below in connection with FIGS. 3-9, the gain profile adjustment circuit 42 causes the selected audio frequency gain profile selected by the user to be altered in the event the user adjusts the volume above a predefined level, for example. By altering the selected audio frequency gain profile in such manner, the mobile phone 10 is able to remain in compliance with any particular sound level limits while still enabling the user more flexibility insofar as the desired audio response of the mobile phone 10.

For example, FIG. 3 represents an exemplary audio frequency gain profile AFGP1 associated with a mobile phone. The horizontal axis represents the particular frequencies across the audio band. The vertical axis represents the gain provided by the DSP 32 with respect to the corresponding frequencies. The vertical position of the audio frequency gain profile AFGP1 is controlled, as will be appreciated, by the user adjusted volume gain of the amplifier 36. Thus, the dashed lines in FIG. 3 represent AFGP1 at different user adjusted volume levels. The curve identified as “LIMIT” represents, in a simplified manner, a limit imposed on the gain provided within the mobile phone 10 as a result of maximum sound level regulations, RLR regulations or the like. Accordingly, AFGP1 max in FIG. 3 represents the maximum volume response of the mobile phone 10 reproducible by the mobile phone 10 without exceeding the LIMIT.

FIG. 4 is analogous to FIG. 3 in that FIG. 4 illustrates an exemplary profile for a different audio frequency gain profile AFGP2. Note that with the particular audio frequency gain profile AFGP2, there is an increased emphasis on the lower bass frequencies and less of an emphasis on the midrange frequencies as compared to the audio frequency gain profile AFGP1 shown in FIG. 3. Consequently, if the mobile phone 10 was designed to permit the user to adjust the volume gain of the mobile phone to achieve the same gain level in the midrange frequencies as reflected by AFGP1 max in FIG. 3, the sound level and/or RLR limits represented by the curve LIMIT would be exceeded at the lower frequencies as represented in FIG. 4.

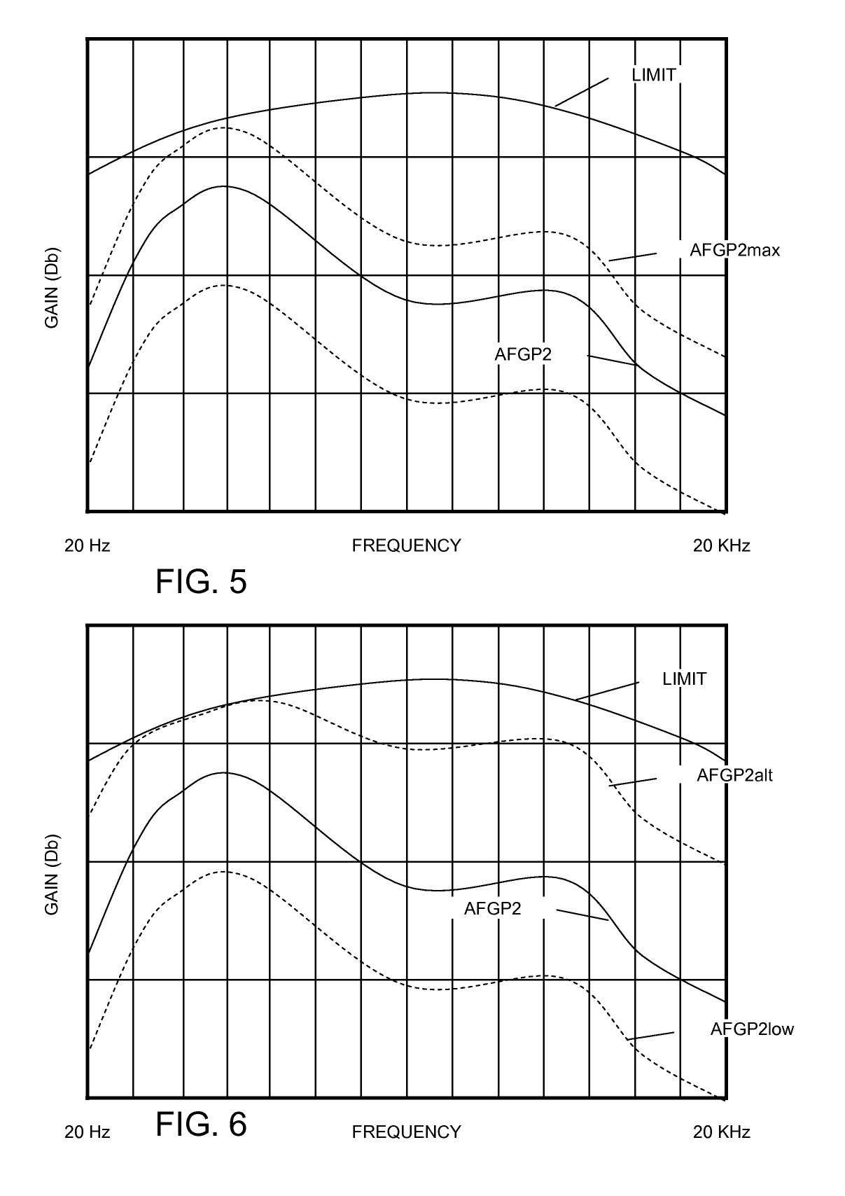

On the other hand, if the mobile phone 10 were designed simply to limit the maximum user adjusted volume gain with respect to the audio frequency gain profile AFGP2 so as to remain within the limits defined by the curve LIMIT, the response illustrated in FIG. 5 would result. Note how the overall gain available in the midrange frequencies is substantially lower than that shown in FIG. 3, for example, due to the audio frequency gain profile AFGP2 being limited in overall volume gain due to the enhanced lower frequency components.

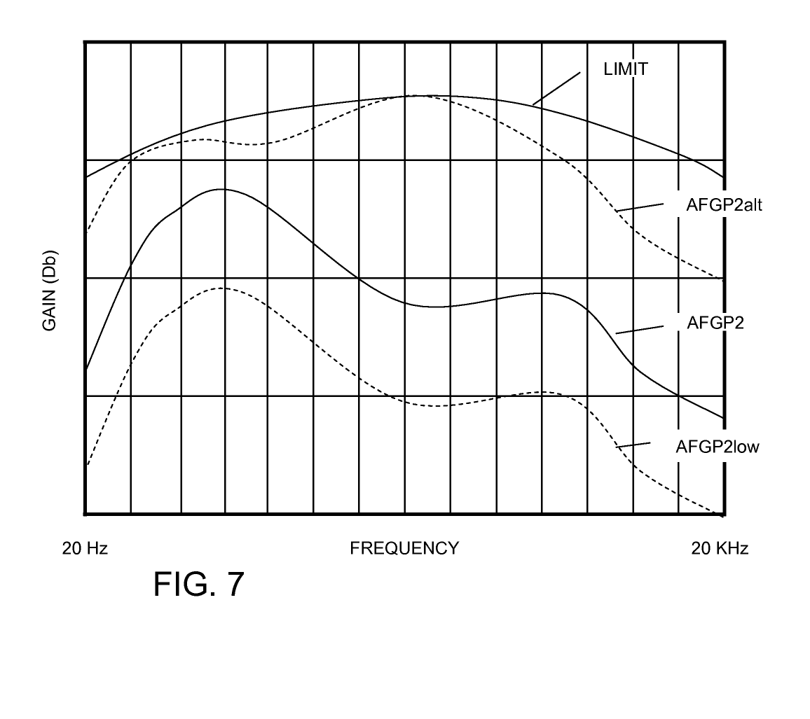

Accordingly, the mobile phone 10 in accordance with the present invention is configured to alter the preselected audio frequency gain profile (e.g., AFGP2) as a function of the user adjusted volume gain as represented in FIG. 6. At lower volume gain settings (e.g., AFGP2 and AFGP2 low), the audio frequency gain profile conforms to the particular audio frequency gain profile selected by the user. At higher volume gain settings where the emphasized bass frequencies otherwise would result in the mobile phone 10 exceeding the LIMIT (FIG. 4) or being undesirably limited (FIG. 5), the gain profile adjustment circuit 42 (FIG. 2) alters the selected audio frequency gain profile. For example, FIG. 6 illustrates how the gain profile adjustment circuit 42 may be operative to scale down the gain coefficients at the lower frequencies while maintaining the gain coefficients at the mid and upper frequencies. As a result, the lower frequencies are suppressed so as to allow the mid and upper frequencies to be reproduced with relatively increased gain.

Such operation is particularly significant in view of the following. It is known that voice signal components produced in the relatively higher audio frequencies approximately in the band of 1 kilohertz (KHz) to 4 KHz results in higher intelligibility than voice components reproduced in the relatively lower frequencies (e.g., such as within the band of 125 Hz to 350 Hz). By altering the audio frequency gain profile AFGP2 in the manner shown in FIG. 6 so as to deemphasize the lower frequency components, the user is better able to adjust the volume to reproduce the voice components in the relatively higher audio frequencies. This better enables the user to listen to the more intelligible voice components without exceeding limits imposed by maximum sound levels, RLR, etc.

The gain profile adjustment circuit 42 not only can function to deemphasize various frequency components as represented in FIG. 6, but may also function to increase other frequency components. For example, FIG. 7 illustrates how the gain profile adjustment circuit 42 may serve to emphasize frequency components in the midrange frequencies in addition to deemphasizing or suppressing the lower frequency components. In such case, the gain profile adjustment circuit 42 is operative to scale down the gain coefficients at the lower frequencies while multiplying or scaling up the gain coefficients at the midrange frequencies.

In this manner, the present invention is particularly useful for altering the frequency response of the mobile phone 10 so that at higher volume levels sound energy can be emphasized in the frequency range most important for speech intelligibility, even in the event the user has selected an audio frequency gain profile that is otherwise less than ideal for speech intelligibility.

The point at which the gain profile adjustment circuit 42 begins to alter the selected audio frequency gain profile of the mobile phone 10 may be virtually any point without departing from the features of the invention in its broadest sense. If the volume control key 38 adjusts the volume across a predefined number of steps or levels (e.g., 11 steps or levels), the gain profile adjustment circuit 42 may be configured to alter the selected audio frequency gain profile only at the last step. Alternatively, the gain profile adjustment circuit 42 may be configured to begin altering the selected audio frequency gain profile gradually as the user adjusted volume gain is increased, for example. Preferably, at the majority of lower levels the selected audio frequency gain profile remains unaltered as will be appreciated.

The gain profile adjustment circuit 42 may be implemented via hardware, software, firmware, or any combination thereof as will be appreciated. Moreover, the gain profile adjustment circuit 42 may be separate from the DSP 32 or may be incorporated within the DSP 32 itself as will be further appreciated. Alternatively, the gain profile adjustment circuit 42 or in combination with the selected audio frequency gain profile may be implemented via a lookup table provided to the DSP 32.

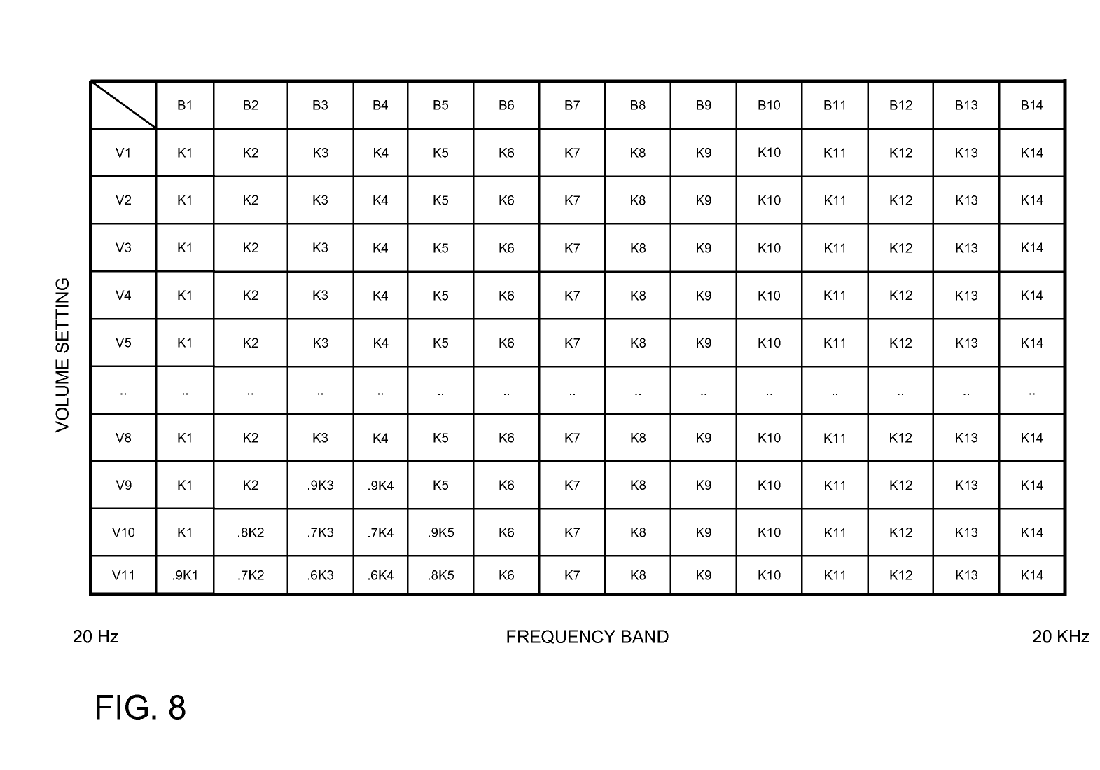

For example, FIG. 8 represents a lookup table for carrying out the operation described above in connection with FIG. 6. Suppose, for example, the user selected audio frequency gain profile AFGP2 has gain coefficients K1-K14 corresponding to frequency bands B1-B14, respectively. Suppose further that the volume gain levels are user adjustable from minimum to maximum in steps V1 to V11. At lower volume levels V1 thru V8, the gain coefficients K1-K14 provided to the DSP 32 for the respective frequency bands B1-B14 remain the same. As the volume level is increased to step V9, however, the lower frequencies in bands B3-B4 begin to be suppressed by scaling down the values of gain coefficients K3 and K4. As the volume level is further increased, the gain coefficients K3 and K4 are further reduced, and the gain coefficients in bands B2 and B5 are also reduced, thus further altering the selected audio frequency gain profile AFGP2. The profile AFGP2 is then further suppressed at the lower frequencies as the volume is increased to level V11.

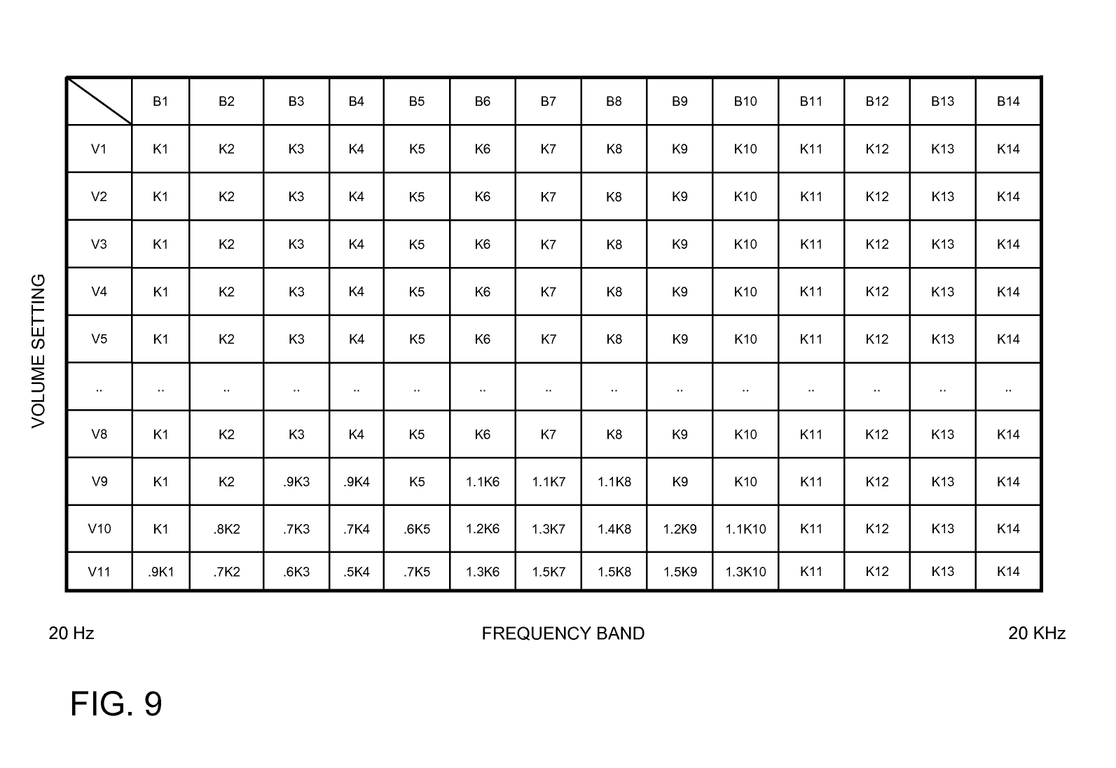

FIG. 9 illustrates an example of such a lookup table for use in accordance with the operation described above in association with FIG. 7. In this example, the midrange frequencies in AFGP2 are emphasized in addition to the lower frequencies being suppressed as described above. Thus, the lookup table includes values for volume levels V9-V11 that scale upward the gain coefficients in bands B6-B10 as the volume is increased. In the lower volume levels V1-V8, the gain coefficients K1-K14 remain at their respective values associated with the user's selected audio frequency gain profile AFGP2.

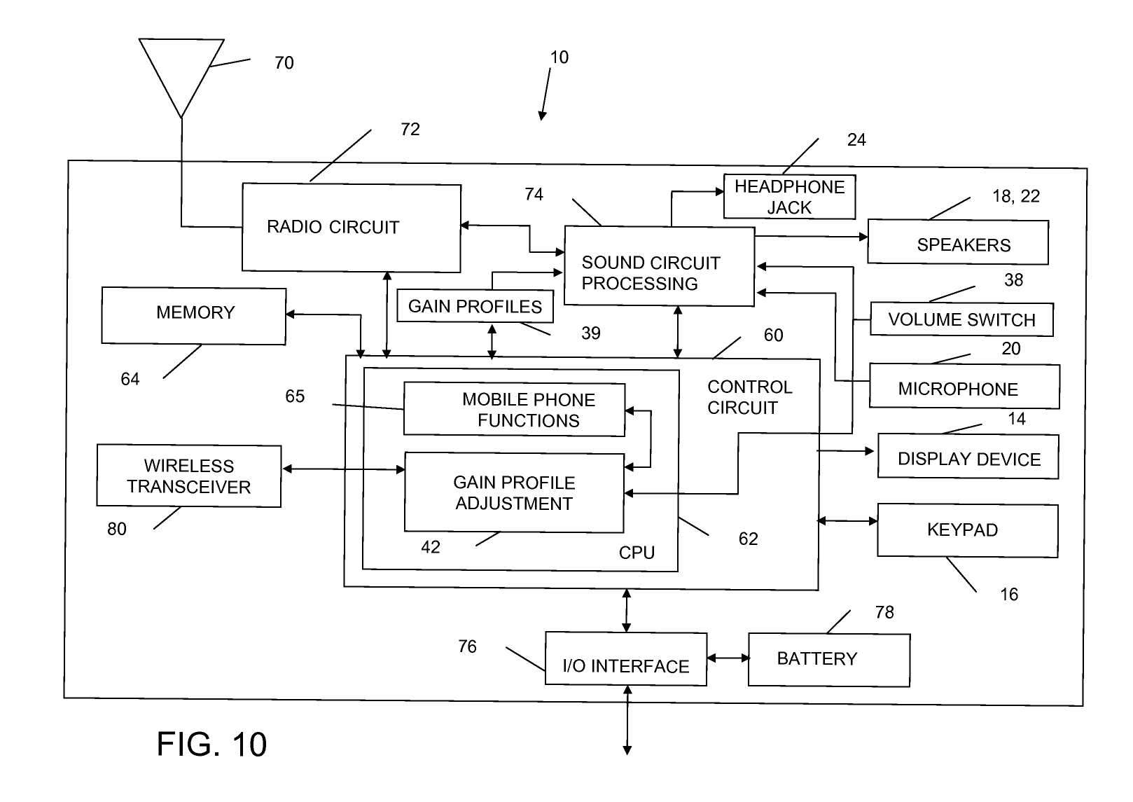

FIG. 10 represents a functional block diagram of the mobile phone 10 in accordance with the present invention. The construction of the mobile phone 10 is generally conventional with the exception of the audio frequency gain profile alteration capabilities described herein. Preferably, such capabilities are implemented primarily via application software within the mobile phone 10. However, it will be apparent to those having ordinary skill in the art that such operation can be carried out via primarily software, hardware, firmware, or combinations thereof, without departing from the scope of the invention.

The mobile phone 10 includes a primary control circuit 60 that is configured to carry out overall control of the functions and operations of the mobile phone 10. The control circuit 60 may include a CPU, microcontroller, or microprocessor, etc., collectively referred to herein simply as a CPU 62. The CPU 62 executes code stored in memory (not shown) within the control circuit 60, and/or in a separate memory 64 in order to carry out conventional operation of the mobile phone functions 65 within the mobile phone 10. In addition, the CPU 62 executes code similarly stored in memory to carry out the functions of the gain profile adjustment circuit 42 in combination with the audio reproduction circuit 26 within the sound processing circuit 74 as described above.

Continuing to refer to FIG. 4, the mobile phone 10 includes an antenna 70 coupled to a radio circuit 72. The radio circuit 72 includes a radio frequency transmitter and receiver for transmitting and receiving signals via the antenna 70 as is conventional. The mobile phone 10 further includes a sound processing circuit 74 that incorporates the audio reproduction circuit 26 and volume gain amplifier 36 as described above in relation to FIG. 2. The sound processing circuit 74 processes the audio signal transmitted by/received from the radio circuit 72. In addition, the sound processing circuit 74 serves to process the audio signal provided by the control circuit 60 during playback of media files as discussed above. Coupled to the sound processing circuit 74 are the speakers 18, 22, the microphone 20 and the headset jack 24. The radio circuit 72 and sound processing circuit 74 are each coupled to the control circuit 60 so as to carry out overall operation.

The mobile phone 10 also includes the aforementioned display 14, keypad 16 and volume control key 38 coupled to the control circuit 60. The mobile phone 10 further includes an I/O interface 76. The I/O interface 76 may be in the form of any one of many typical mobile phone I/O interfaces, such as a multi-element connector at the base of the mobile phone 10. As is typical, the I/O interface 76 may be used to couple the mobile phone 10 to a battery charger to charge a power supply unit (e.g., battery) 78 within the mobile phone 10. Further, the I/O interface 76 may serve to connect the mobile phone 10 to a personal computer or other device via a data cable, etc. As another alternative, the I/O interface 76 may serve to connect the mobile phone 10 to a docking station including an audio amplifier, speakers and/or video display to allow for enhanced viewing/listening of the media objects as part of the media player function.

The mobile phone 10 further includes a Bluetooth transceiver 80 for enabling wireless handsfree operation. In the case of the present invention, the audio signal provided to a Bluetooth headset may be processed in the manner discussed above prior to being transmitted to the headset via the transceiver 80. Of course, the above-described principles can be implemented in the Bluetooth headset itself.

Accordingly, those having ordinary skill in the art will appreciate that the present invention provides electronic equipment functional to preserve the user's flexibility in personalizing audio reproduction. Specifically, the present invention provides for electronic equipment that allows a user to still enjoy dynamic audio reproduction despite sound level limits due to RLR, maximum sound levels, etc.

The term “electronic equipment” as referred to herein includes portable radio communication equipment. The term “portable radio communication equipment”, also referred to herein as a “mobile radio terminal”, includes all equipment such as mobile phones, pagers, communicators, e.g., electronic organizers, personal digital assistants (PDAs), smartphones or the like. Moreover, the term “electronic equipment” includes personal and portable audio/media reproduction devices including CD players, DVD players, flash memory based media players, hard drive based media players, etc. The present invention has utility as part of each of these types of electronic equipment.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. An electronic equipment, comprising:
an audio reproduction circuit for receiving an audio signal and reproducing the audio signal in accordance with a preselected audio frequency gain profile;
a volume gain control circuit for providing user adjustable volume gain to the audio signal reproduced by the audio reproduction circuit; and
an audio output for outputting the reproduced audio signal,
wherein the audio reproduction circuit alters the preselected audio frequency gain profile as a function of the user adjusted volume gain.

2. The electronic equipment of claim 1, wherein the audio reproduction circuit adjusts the audio frequency gain profile by reducing the gain at relatively lower audio frequencies as a result of the user adjusted volume gain being increased.

3. The electronic equipment of claim 2, wherein the relatively lower audio frequencies include frequencies approximately within the band of 125 Hz to 350 Hz.

4. The electronic equipment of claim 2, wherein the audio reproduction circuit adjusts the audio frequency gain profile by increasing the gain at relatively higher audio frequencies as a result of the user adjusted volume gain being increased.

5. The electronic equipment of claim 4, wherein the relatively higher audio frequencies include frequencies in the band of approximately 1 KHz to 4 KHz.

6. The electronic equipment of claim 1, wherein the audio reproduction circuit adjusts the audio frequency gain profile to increase the intelligibility of voice signals within the reproduced audio signal as a result of the user adjusted volume gain being increased.

7. The electronic equipment of claim 1, wherein the audio reproduction circuit alters the preselected audio frequency gain profile at relatively higher user adjusted volume gains but does not alter the preselected audio frequency gain profile at relatively lower user adjusted volume gains.

8. The electronic equipment of claim 1, wherein the audio reproduction circuit alters the preselected audio frequency gain profile so as to maintain a sound level below a preselected level despite the user adjusted volume gain being increased.

9. The electronic equipment of claim 1, wherein the audio reproduction circuit keeps the preselected audio frequency gain profile substantially the same throughout a majority of the volume gain adjustment provided by the volume gain control circuit, and alters the preselected audio frequency gain profile substantially only towards the maximum volume gain provided by the volume gain control circuit.

10. The electronic equipment of claim 1, wherein the audio reproduction circuit includes a gain profile adjustment circuit that scales the preselected audio frequency gain profile in order to alter the preselected audio frequency gain profile as a function of the user adjusted volume gain.

11. The electronic equipment of claim 10, wherein the preselected audio frequency gain profile and gain profile adjustment circuit are implemented via a lookup table.

12. The electronic equipment of claim 1, wherein the preselected audio frequency gain profile is user adjustable.

13. The electronic equipment of claim 12, wherein the user may select the preselected audio frequency gain profile from among a plurality of audio frequency gain profiles.

14. The electronic equipment of claim 13, wherein at least one of the plurality of audio frequency gain profiles is configured for improved music reproduction, and at least another one of the plurality of audio frequency gain profiles is configured for improved voice reproduction.

15. The electronic equipment of claim 1, wherein the electronic equipment comprises at least one of a mobile phone, personal audio player, and personal video player.

16. The electronic equipment of claim 15, wherein the electronic equipment is a mobile phone.

17. The electronic equipment of claim 16, wherein the mobile phone comprises a speaker and a hands-free headset output, each of which may be coupled to the audio output.

18. The electronic equipment of claim 1, wherein the electronic equipment is a wireless hands-free headset.

19. The electronic equipment of claim 18, wherein the headset includes a Bluetooth receiver.

20. A method for controlling gain in an electronic equipment, comprising the steps of:
reproducing the audio signal in accordance with a preselected audio frequency gain profile;
providing adjustable volume gain to the audio signal reproduced by the audio reproduction circuit; and
altering the preselected audio frequency gain profile as a function of the adjustable volume gain.
